(19) United States
(12) Patent Application Publication
(10) Pub. No.: US 2009/0273348 A1
(43) Pub. Date: Nov. 5, 2009

(54) CHAMBER APPARATUS AND METHOD OF MANUFACTURE THEREOF

(76) Inventor: Neil Charles Tigwell, Oxon (GB)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/417,758

(22) Filed: Apr. 3, 2009

(30) Foreign Application Priority Data
Apr. 4, 2008 (GB) 0806129.3

(51) Int. Cl. G01R 33/34

(52) U.S. Cl. 324/318; 29/428

(57) ABSTRACT

A chamber apparatus comprises a chamber housing for maintaining a vacuum. The housing has a bore tube bounded by a substantially cylindrical wall formed at least in part from a coil suspended in a substantially non-metallic material.

### BACKGROUND OF THE INVENTION

1. Field of the Invention

The present invention relates to a chamber apparatus of the type that, for example, is used to contain a cryogen vessel in a vacuum. The present invention also relates to a method of manufacturing a chamber apparatus of the type that, for example, is used to contain a cryogen vessel in a vacuum.

2. Description of the Prior Art

In the field of nuclear Magnetic Resonance Imaging (MRI), a magnetic resonance imaging system typically comprises a superconductive magnet, a gradient coil system, field coils, shim coils and a patient table. The superconductive magnet is provided in order to generate a strong uniform static magnetic field, known as the B₀ field, in order to polarize nuclear spins in an object under test. The gradient coil system typically comprises three paired orthogonal coils disposed within the superconductive magnet in order to produce gradient magnetic fields. When in use, the gradient magnetic fields are superimposed collectively and sequentially on the static magnetic field in order to provide selective spatial excitation of an imaging volume associated with the object under test. Also, a so-called body coil is provided to transmit and/or receive Radio Frequency (RF) signals in order improve imaging quality with respect to a region of interest in the object under test.

A known cryogen-cooled conventional superconductive magnet apparatus includes a cryostat including a cryogen vessel. A cooled superconductive magnet is provided within the cryogen vessel, the cryogen vessel being retained within an outer vacuum chamber (OVC). One or more thermal radiation shields are provided in a vacuum space between the cryogen vessel and the OVC. In some known arrangements, a refrigerator is mounted in a refrigerator sock located in a turret towards the side of the cryostat, the refrigerator being provided for the purpose of maintaining the temperature of a cryogen provided in the cryogen vessel. The OVC is typically formed from two co-axial stainless steel cylinders, capped at both ends by so-called centrally-apertured “end spinnings” that are welded to the ends of the co-axial cylinders. An inner cylinder of the co-axial cylinders constitutes a so-called bore tube to permit a patient or other object under test to reside within the field of the superconductive magnet apparatus.

The gradient coils and the body coils are each typically suspended or “potted” in resin, which results in structures that are cylindrical in shape. The potted gradient coils are co-axially located within and adjacent to bore tube. Similarly, the potted body coil is co-axially located within the potted gradient coils. The provision of the co-axial gradient and body coils serve to reduce a cylindrical volume of the bore tube.

In the field of tomography, particularly magnetic resonance tomography, it is advantageous to maximize the cylindrical volume of the bore tube in order to accommodate, inter alia, as physically large patients as possible. Consequently, the loss of volume of the bore tube as a result of the volume occupied by the gradient and field coils is disadvantageous.

Additionally, the provision of the gradient and body coils concentrically within the bore tube of the OVC requires a complicated and relatively slow manufacturing process due to the sequential nature of assembly of the superconductive magnet apparatus. In this respect, heavy coil components need to be loaded into the bore tube. The positions of the coils relative to the superconductive magnet and each other also need to be adjusted, and a large number of interconnections need to be established in relation to the coils.

### SUMMARY OF THE INVENTION

According to a first aspect of the present invention, there is provided a chamber apparatus having a chamber housing for maintaining a vacuum, the housing having a bore tube bounded by a substantially cylindrical wall formed at least in part from a first coil suspended in a substantially non-metallic material. The housing comprises a head part and an end part, the head part having a first peripheral returning portion and a bore tube portion defining the bore tube.

The head part may be substantially mushroom-shaped.

The end part may be arranged to sealingly co-operate with the head part in order to prevent, when in use, loss of a vacuum in a volume bounded by the housing.

The housing may be arranged to sealingly co-operate with a support structure.

The head part may be arranged to sealingly co-operate with a first portion of the support structure.

The end part may be arranged to sealingly co-operate with a second portion of the support structure.

The housing may be formed in part from a substantially non-metallic material.

The first coil may be a gradient coil.

The apparatus may further have a second coil suspended in a substantially non-metallic material, the second coil radially adjacent least part of the first coil.

The first coil may be a Radio-Frequency coil and the second coil may be a gradient coil. The first coil may be a body coil.

The first peripheral returning portion may comprise a first void space substantially bounded by a periphery surface thereof. The end part may have a second void space substantially bounded by a periphery surface thereof.

An electrical conductor may extend through the first void space. An electrical conductor may extend through the second void space.

A conduit for carrying a coolant therein may extend through the first void space. A conduit for carrying a coolant therein may extend through the second void space.

The present invention also provides a tomography system that includes the chamber apparatus according to the present invention.

The present invention also provides a method of manufacturing a chamber apparatus. The method includes forming a head part of a chamber housing, having a first peripheral returning portion and a bore tube portion defining a bore tube, the bore tube portion having a substantially cylindrical wall bounding the bore tube, the substantially cylindrical wall being formed at least in part from a coil suspended in a substantially non-metallic material; forming an end part of the chamber housing, having a second peripheral returning portion; and sealingly coupling at least part of the head part with at least part of the end part.

The end part may sealingly co-operate with the head part in order to prevent, when in use, loss of a vacuum in a volume bounded by the housing.

The housing may sealingly co-operate with a support structure.

The head part may sealingly co-operate with a first portion of the support structure. The end part may sealingly co-operate with a second portion of the support structure.

It is thus possible to provide a chamber apparatus and a method of manufacture thereof that maximizes volume of a bore tube. It is also possible to provide reduced manufacture time, particularly in relation to assembly as well as increased flexibility in terms of location of assembly, in particular encapsulation of a cryogen vessel and provision of the first and second co-axial coils.

### BRIEF DESCRIPTION OF THE DRAWINGS

At least one embodiment of part of the invention will now be described, by way of example only, with reference to the accompanying drawings.

FIG. 1 is a schematic diagram in part-cross section of a cryogen vessel, and a chamber apparatus constituting an embodiment of the invention.

FIG. 2 is a schematic diagram in cross section of the chamber apparatus of FIG. 1.

FIG. 3 is a schematic diagram in cross-section of another chamber apparatus constituting another embodiment of the invention.

FIG. 4 is a schematic diagram of in cross section of another chamber Apparatus constituting another embodiment of the invention.

### DESCRIPTION OF THE PREFERRED EMBODIMENTS

Throughout the following description identical reference numerals will be used to identify like parts.

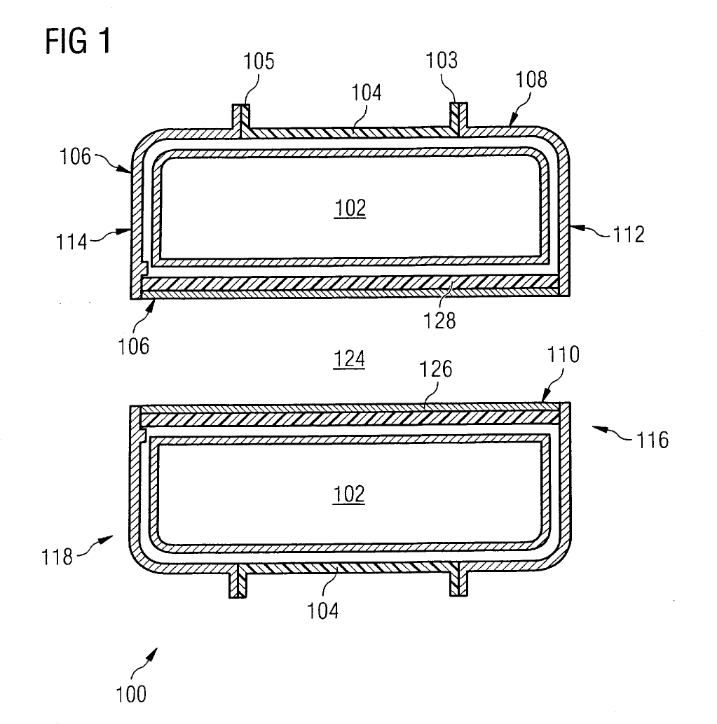

Referring to FIG. 1, a superconductive magnet apparatus 100 of, for example, a tomography system, such as an MRI system, has a cryogen vessel 102, the cryogen vessel 102 containing a pair of coils (not shown) formed from a superconductive material, for example a Niobium-Titanium alloy. The pair of coils is immersed in a cryogen, for example cooled Helium, contained within the cryogen vessel 102. The superconductive magnet apparatus 100 also comprises a support structure 104 from which the cryogen vessel 102 is suspended. In this example, the support structure 104 is centrally located around the cryogen vessel 102 and has a first circumferential lip 103 spaced from a second circumferential lip 105.

As those skilled in the art are aware of the structure of the cryogen vessel 102 and the contents thereof, for example the superconductive coils, for the sake of simplicity and conciseness of description, the superconductive magnet apparatus 100 need not be described in further detail herein.

The cryogen vessel 102 is contained within a housing 106 that maintains, when in use, a vacuum therein. In this example, the chamber 106 is known as an Outer Vacuum Chamber (OVC). The OVC 106 has an outer cylindrical wall 108 and an inner cylindrical wall 110, a first end wall 112 extending between and the outer wall 108 and the inner wall 110 at a first end thereof and a second end wall 114 extending between and the outer wall 108 and the inner wall 110 at a second end thereof. The resulting housing 106 defines an internal space, or chamber, for locating the cryogen vessel 102 therein.

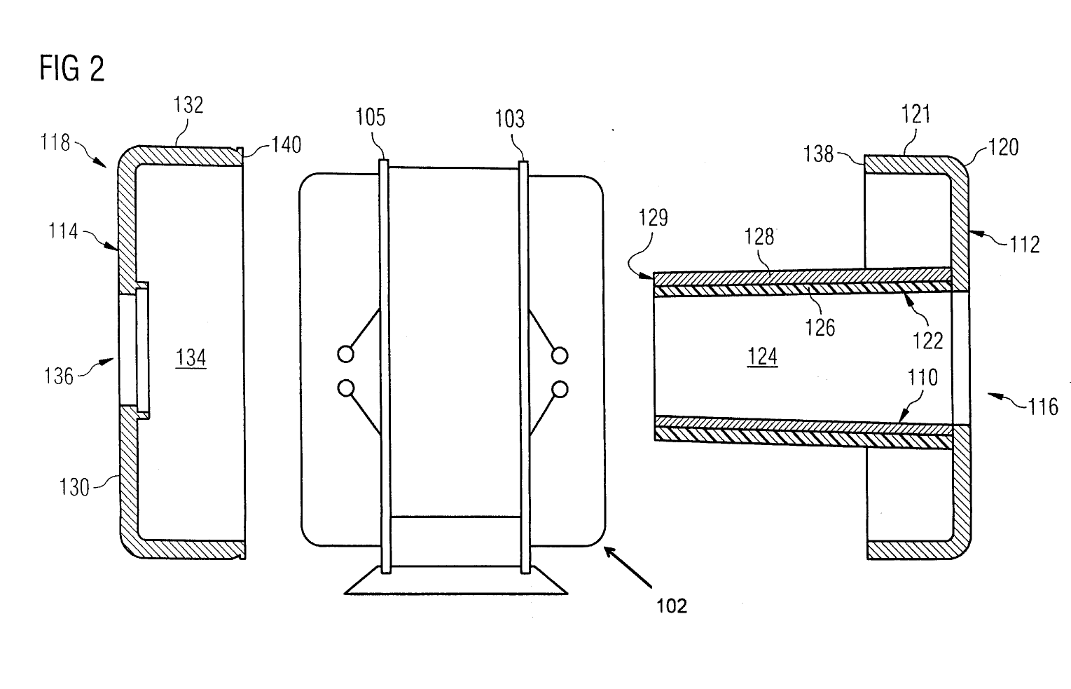

In this example, the housing 106 is formed from a substantially non-metallic material. Furthermore, the housing 106 is formed, in this example, in two parts: a head part 116 and an end part 118. Referring to FIG. 2, the head part 116 has a peripheral returning portion 120 and a bore tube portion 122. The first end wall 112 of the peripheral returning portion 120 extends radially outwards and then returns toward a central location of the housing 106 to form a first circumferential side wall 121 that is, in this example, substantially perpendicular to the first end wall 112. The bore tube portion 122 and the head part 116 are formed so as to be a single part. Formation of the peripheral returning portion 120 with the bore tube portion 122 as a single unit can be by coupling using an adhesive or a mechanical connection using one or more seals. The head part 116 is substantially mushroom-shaped.

The bore tube portion 122 includes the inner cylindrical wall 110 that bounds a bore tube 124 when the housing is assembled. The bore tube portion 122 is formed, at least in part, from a first coil unit 126 suspended in a non-metallic material, for example the first coil unit 126 may be potted in resin. The first coil unit 126 suspended (or encapsulated) in non-metallic material serves to provide the inner cylindrical wall 110. In this example, the coil is a Radio-Frequency coil, for example a body coil. A second coil unit 128 suspended (or encapsulated) in a non-metallic material lies radially adjacent at least part of the first coil unit 126 and surrounds, at least in part, the first coil unit 126. In this example, the second coil unit 128 suspended in non-metallic material is a set of gradient coils. The bore tube portion 122 has a distal end 129 formed for engagement with the end part 118.

The end part 118 is a circular recessed portion of material having a base portion 130 integrally formed with a second circumferential side wall 132 to define an open cavity 134. The base portion 130 constitutes the second end wall 114 and has a substantially centrally located aperture 136 and is formed to cooperatively engage the distal end 129 of the bore tube portion 122. In this example, the end part 118 is formed from the same non-metallic material as the head part 120, for example glass-reinforced plastic or carbon fiber reinforced plastic.

The first side wall 121 of the peripheral portion 120 has a first circumferential rim 138. Similarly, the second side wall 132 of the end part 118 has a second circumferential rim 140.

After formation of the head part 116 and the end part 118, the head part 116 is offered to a first end of the cryogen vessel 102, the bore tube portion 122 passing into a central internal bore (not shown) of the cryogen vessel 102 and the peripheral returning portion 120 covering the first end of the cryogen vessel 102. The end part 118 is offered to a second end of the cryogen vessel 102 and placed over the second end of the cryogen vessel 102 in order to cover the second end thereof. In this example, the first rim 138 of the peripheral returning portion 120 abuts the first lip 103 of the support structure 104 in a sealing manner using, for example, a first circumferential seal (not shown) or an adhesive capable of providing a seal. Similarly, the second rim 140 of the circumferential side wall 132 of the end part 118 abuts the second lip 105 of the support structure 104 in a sealing manner using, for example, a second circumferential seal (not shown) or an adhesive capable of providing a seal. Additionally, the distal end 129 of the bore tube portion 122 is coupled to an internal surface of the aperture 136 in a sealing manner using, for example, a third circumferential seal or an adhesive capable of providing a seal.

Atmosphere between the cryogen vessel 102 and the completed housing 106 is then evacuated in order to provide a vacuum within the housing 106. Where seals alone are employed between parts of the housing 106 and the support structure 104, the vacuum created serves to maintain the head part 116 and the end part 118 in situ. Similarly, where seals are not exclusively employed, the vacuum created serves to contribute the maintenance of the head part 116 and the end part 118 in situ. Of course, those skilled in the art will appreciate that other constructional features may need to be provided, for example thermal shields, before closure and evacuation of the housing 106. However, as mentioned above, in order to preserve simplicity and conciseness of description, such details are not described herein.

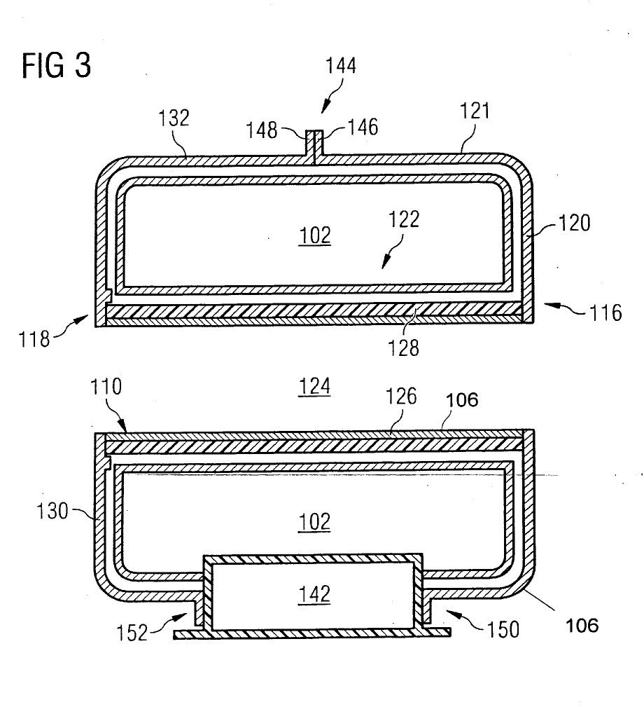

In another embodiment (FIG. 3), the cryogen vessel 102 is no longer suspended from the support structure of FIGS. 1 and 2. Instead, a pedestal-type support structure 142 is located beneath the cryogen vessel 102 to support the cryogen vessel 102 from beneath.

Consequently, the housing 106 is configured differently in order to accommodate the pedestal-type support structure 142. In this respect, the side wall 132 of the end part 118 extends further and the side wall 121 of the peripheral portion 120 also extends further so that the respective rims 138, 140 of the end walls 132, 121 meet at a substantially central location 144 with respect to the cryogen vessel 102 when the housing 106 is assembled. In this example, the rims 138, 140 are respectively provided with lips 146, 148 in order to provide increased abutment surfaces. The peripheral portion 120 has a first shortened region 150 and the end part 118 also has a second shortened region 152 in order to provide a space to accommodate the pedestal-type support structure 142 when the housing 106 is assembled.

Where the lips 138, 140 of the end part 118 and the peripheral portion 120 abut, the end part 118 and the peripheral portion 120 do so in a sealing manner, for example using a seal (not shown) or an adhesive capable of providing a seal. Around the periphery of the pedestal-type support structure 140, the lips 138, 140 of the end part 118 and the peripheral portion 120 at the first and second shortened regions 150, 152 abut the periphery of the pedestal-type support structure 142 in a sealing manner, for example using a seal (not shown) or an adhesive capable of providing a seal.

For the avoidance of doubt, the head part 116 is formed in a like manner to any example described above in the previous embodiment in order that the head part 116 includes the bore tube portion 122.

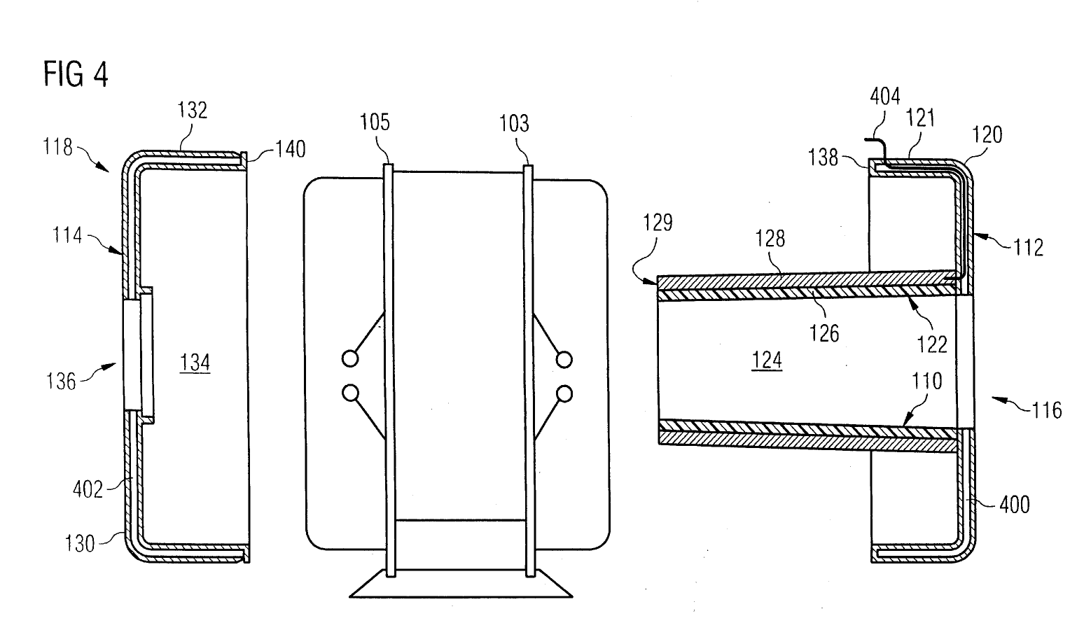

In another embodiment (FIG. 4), the peripheral returning portion 120 of the head part 116 and the end part 118 has a first void space 400 and a second void space 402, respectively. In this example, the first and second void spaces 400, 402 are substantially bound by respective peripheral surfaces of the peripheral returning portion 120 and the end part 118. The first and second void spaces 400, 402 are filled with a composite foam material. Although the first and second void spaces 400, 402 extend throughout the peripheral returning portion 120 and the end part 118. Those skilled in the art will appreciate that the first void space 400 can extend through only part of the peripheral returning portion 120 and/or the second void space 402 can extend through only part of the end part 118.

A lead 404, for example a gradient coil power lead, extends through the first void space 400 of the peripheral returning portion 120 to the second coil unit 128, for example a set of gradient coils in order to couple the second coil unit to a suitable power supply (not shown). Those skilled in the art will appreciate that the lead 404 preferably has a pair of electrical conductors. In addition to the lead 404 for the second coil unit, a further lead can be provided to extend through the first void space 400 of the peripheral returning portion 120 in order to couple the first coil unit 126, for example a body coil, to another suitable power supply. Additionally, although not shown, one or more coolant conduits, for example one or more pipes can be provided and extend through the first void space 400 of the peripheral returning portion 120 in order to support a fluid circuit to one or both of the first and second coil units in order to ensure that one or both coil units are maintained at respective optimum operating temperatures.

Although not illustrated, one or more electrical conductor(s) and/or one or more coolant conduit(s) may extend through second void space 402 in addition to, or instead of, conductor(s) and/or conduit(s) extending through first void space 400.

In such embodiments, the housing 106 forms a subassembly comprising one or more coils with electrical conductor(s) and/or coolant conduit(s). Such assemblies may be manufactured and tested remotely from the magnet fabrication itself, simplifying final assembly of the completed system.

Although the above embodiments have been described in the context of a superconductive magnet cooled by a cryogen, the skilled person should appreciate that other types of superconductive magnet constructions can be contained in the housing 106, for example a superconductive magnet cooled by conduction. Likewise, although use of seals and/or adhesive have been described above to provide sealed coupling, those skilled in the art will appreciate that other coupling and/or sealing techniques can be employed, for example ultrasonic welding where non-metallic materials permit.

I claim as my invention:

1. A chamber apparatus comprising:
a chamber housing with a vacuum maintained therein;
a bore tube proceeding into an interior of the housing, said bore tube having a substantially cylindrical wall formed at least in part by a coil suspended in a substantially non-metallic material; and
said chamber housing comprising a head part and an end part, said head part having a first peripheral return portion and a bore tube portion defining said bore tube.

2. An apparatus as claimed in claim 1 wherein said head part is substantially mushroom-shaped.

3. An apparatus as claimed in claim 1 wherein said end part is in sealing connection with said head part to prevent loss of said vacuum.

4. An apparatus as claimed in claim 1 comprising a support structure connected in a sealing relationship with said housing.

5. An apparatus as claimed in claim 4 wherein said head part is in sealing relation with a portion of said support structure.

6. An apparatus as claimed in claim 5 wherein said portion of said support structure is a first portion of said support structure, and wherein said end part is in sealing relationship with a second portion of said support structure.

7. An apparatus as claimed in claim 1 wherein said housing is comprised in part of a substantially non-metallic material.

8. An apparatus as claimed in claim 1 wherein said coil is a magnetic resonance gradient coil.

9. An apparatus as claimed in claim 1 wherein said coil is a first coil, and comprising a second coil suspended in a substantially non-metallic material, said second coil being radially adjacent at least a part of said first coil.

10. An apparatus as claimed in claim 9 wherein said first coil is a magnetic resonance radio frequency coil, and said second coil is a magnetic resonance gradient coil.

11. An apparatus as claimed in claim 10 wherein said first coil is a body coil.

12. An apparatus as claimed in claim 1 wherein said return portion comprises a void space substantially bounded by a periphery surface of said return portion.

13. An apparatus as claimed in claim 12 wherein said void space is a first void space, and wherein said end part comprises a second void space bounded by a periphery surface of said end part.

14. An apparatus as claimed in claim 13 comprising an electrical conductor extending through said first void space.

15. An apparatus as claimed in claim 13 comprising an electrical conductor proceeding through said second void space.

16. An apparatus as claimed in claim 13 comprising a conduit carrying a coolant extending through said first void space.

17. An apparatus as claimed in claim 13 comprising a conduit carrying a coolant extending through said second void space.

18. A method for manufacturing a chamber apparatus, comprising the steps of:
forming a head part of a chamber housing having a peripheral return portion and a bore tube portion defining a bore tube, said bore tube having a substantially cylindrical wall bounding the bore tube, and forming the substantially cylindrical wall at least in part by a coil suspended in a substantially non-metallic material;
forming an end part of the chamber housing having a second peripheral return portion; and
sealingly coupling at least part of said head part with at least part of said end part.

19. A method as claimed in claim 18 comprising evacuating said chamber housing to form a vacuum in an interior thereof, and maintaining loss of said vacuum by sealing said head part with said end part.

20. A method as claimed in claim 19 comprising placing said housing in sealing relation with a support structure.

21. A method as claimed in claim 20 comprising placing said head part in sealing relation with a portion of said support structure.

22. A method as claimed in claim 21 wherein said portion of said support structure is a first portion of said support structure, and comprising placing said end part in sealing relation with a second portion of said support structure.
